(19) United States
(12) Patent Application Publication
(10) Pub. No.: US 2026/0354284 A1
(43) Pub. Date: Nov. 5, 2026

(54) SEMICONDUCTOR PACKAGE AND METHOD FOR FORMING THE SAME

(71) Applicant: JCET STATS ChipPAC Korea Limited, Incheon (KR)

(72) Inventors: MinSung LEE, Incheon (KR); YeoJun YUN, Incheon (KR); HeeSoo LEE, Incheon (KR)

(21) Appl. No.: 19/661,691

(22) Filed: Apr. 29, 2026

(30) Foreign Application Priority Data
Apr. 30, 2025 (CN) 202510566548.0

(51) Int. Cl. H10W 90/28; H10W 72/90; H10W 90/00; H10W 90/20

(52) U.S. Cl. CPC H10W 90/28; H10W 72/952; H10W 90/271; H10W 90/291; H10W 90/792; H10W 90/794

(57) ABSTRACT

A semiconductor package and a method for forming the same are provided. The method includes: providing a first semiconductor die having a first active surface and a first non-active surface; providing a second semiconductor die having a second active surface and a second non-active surface, wherein at least one wire-bonding pad is formed on the second active surface of the second semiconductor die; attaching the first active surface of the first semiconductor die to the second active surface of the second semiconductor die using hybrid bonding, wherein the at least one wire-bonding pad is exposed from the first semiconductor die; providing a sub-package including a substrate and a third semiconductor die mounted on the substrate; attaching the second non-active surface of the second semiconductor die to the third semiconductor die; and electrically coupling the at least one wire-bonding pad to the substrate using wire bonding.

### TECHNICAL FIELD

The present application generally relates to semiconductor technology, and more particularly, to a semiconductor package and a method for forming the same.

### BACKGROUND OF THE INVENTION

The semiconductor industry is constantly faced with complex integration challenges as consumers want their electronics to be smaller, faster and higher performance with more and more functionalities packed into a single device. To form a stacked chip package, wire bonding techniques are commonly used to bond an upper chip to a lower chip or a substrate. However, the wire bonding technique may limit performance in high-speed applications and increase the overall package size due to the height of the bonding wires.

Therefore, a need exists for a method for forming a semiconductor package with higher data transmission speed and/or reduced height.

### SUMMARY OF THE INVENTION

An objective of the present application is to provide a method for forming a semiconductor package with higher data transmission speed and/or reduced height.

According to an aspect of the present application, a method for forming a semiconductor package is provided. The method may include: providing a first semiconductor die having a first active surface and a first non-active surface opposite to the first active surface; providing a second semiconductor die having a second active surface and a second non-active surface opposite to the second active surface, wherein at least one wire-bonding pad is formed on the second active surface of the second semiconductor die; attaching the first active surface of the first semiconductor die to the second active surface of the second semiconductor die using hybrid bonding, wherein the at least one wire-bonding pad is exposed from the first semiconductor die; providing a sub-package including a substrate and a third semiconductor die mounted on the substrate; attaching the second non-active surface of the second semiconductor die to the third semiconductor die; and electrically coupling the at least one wire-bonding pad to the substrate using wire bonding.

According to another aspect of the present application, a semiconductor package is provided. The semiconductor package may include: a first semiconductor die having a first active surface and a first non-active surface opposite to the first active surface; a second semiconductor die having a second active surface and a second non-active surface opposite to the second active surface, wherein at least one wire-bonding pad is formed on the second active surface of the second semiconductor die, and the first active surface of the first semiconductor die is attached to the second active surface of the second semiconductor die using hybrid bonding such that the at least one wire-bonding pad is exposed from the first semiconductor die; and a sub-package including a substrate and a third semiconductor die mounted on the substrate, wherein the second non-active surface of the second semiconductor die is attached to the third semiconductor die, and the at least one wire-bonding pad is electrically coupled to the substrate using wire bonding.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view of a semiconductor package having a semiconductor die stack.

FIG. 2A is a cross-sectional view of a semiconductor package according to an embodiment of the present application.

FIG. 2B is an enlarged view of a portion of the semiconductor package shown in FIG. 2A according to an embodiment.

FIG. 2C is an enlarged view of a portion of the semiconductor package shown in FIG. 2A according to another embodiment.

FIG. 2D is an enlarged view of a portion of the semiconductor package shown in FIG. 2A according to another embodiment.

FIG. 2E is an enlarged view of a portion of the semiconductor package shown in FIG. 2A according to another embodiment.

FIG. 3 is a cross-sectional view of a semiconductor package according to another embodiment of the present application.

FIGS. 4A-4H are cross-sectional illustrating various steps of a method for forming a semiconductor package according to an embodiment of the present application.

FIGS. 5A-5C are cross-sectional illustrating various steps of a method for forming a semiconductor die stack according to an embodiment of the present application.

FIGS. 6A-6D are cross-sectional illustrating various steps of a method for forming a semiconductor die stack according to another embodiment of the present application.

FIGS. 7A-7C are cross-sectional illustrating various steps of a method for forming a semiconductor die stack according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

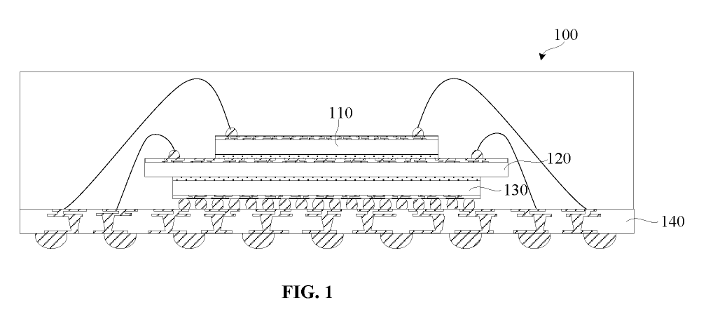

FIG. 1 is a cross-sectional view of a semiconductor package 100 having a semiconductor die stack. The semiconductor die stack include a first semiconductor die 110, a second semiconductor die 120 and a third semiconductor die 130 stacked vertically. Specifically, the third semiconductor die 130 is flip-chip bonded to a substrate 140, and the second semiconductor die 120 is back-side attached to the third semiconductor die 130 and then wire-bonded to the substrate 140. Further, the first semiconductor die 110 is back-side attached to the second semiconductor die 120 and then wire-bonded to the substrate 140. However, traditional wire-bonding methods face challenges, such as delays in electrical signal transmission. For example, these methods typically support data transmission speeds of only 1-5 Gbps, limiting performance in high-speed applications. Additionally, the height of the bonding wires increases the overall package size. For example, the wire height can cause the package thickness to reach 1-2 mm, posing a significant challenge to the miniaturization of electronic devices.

To address at least one of the above problems, a method for forming a semiconductor package is provided. In the method, an active surface of a first semiconductor die is attached to an active surface of a second semiconductor die using hybrid bonding, while at least one wire-bonding pad formed on the active surface of the second semiconductor die is exposed from the first semiconductor die. Then, the semiconductor die stack including the first semiconductor die and the second semiconductor die is attached to a third semiconductor die mounted on a substrate. Afterwards, the at least one wire-bonding pad is electrically coupling to the substrate using wire bonding. In this method, the first semiconductor die is initially electrically coupled to the second semiconductor die using hybrid bonding. It can then be further electrically coupled to the substrate via the second semiconductor die and the bonding wires. Thus, there is no need to wire-bond the first semiconductor die directly to the substrate. Compared to wire-bonding, hybrid bonding technique can significantly enhance signal transmission speeds, for example, enabling rates of tens to hundreds of Gbps and reducing delays by approximately a factor of 10. By eliminating the need for bonding wires, hybrid bonding allows for a more compact design and reduces package thickness by about, for example, 50%.

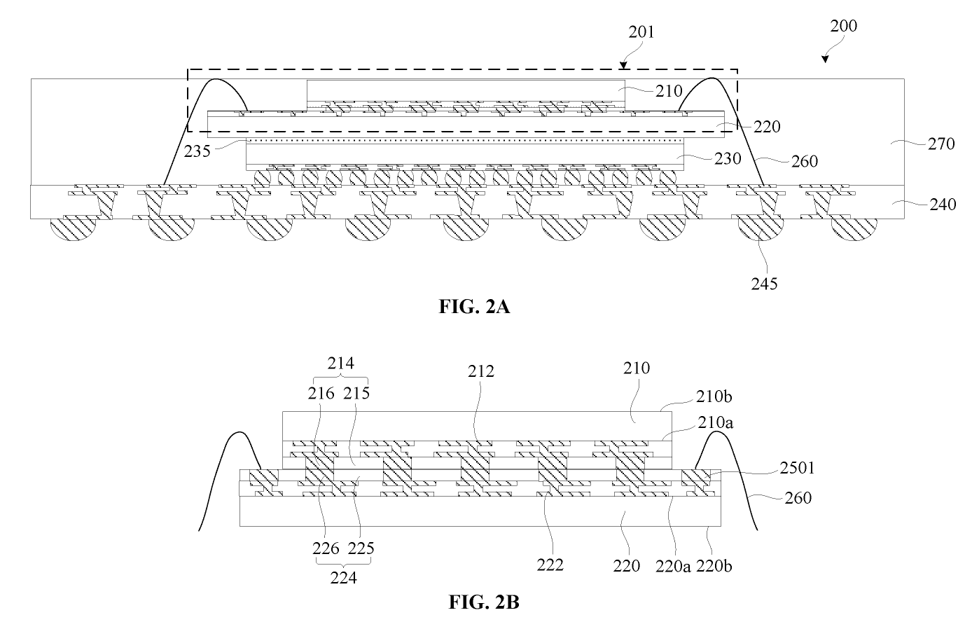

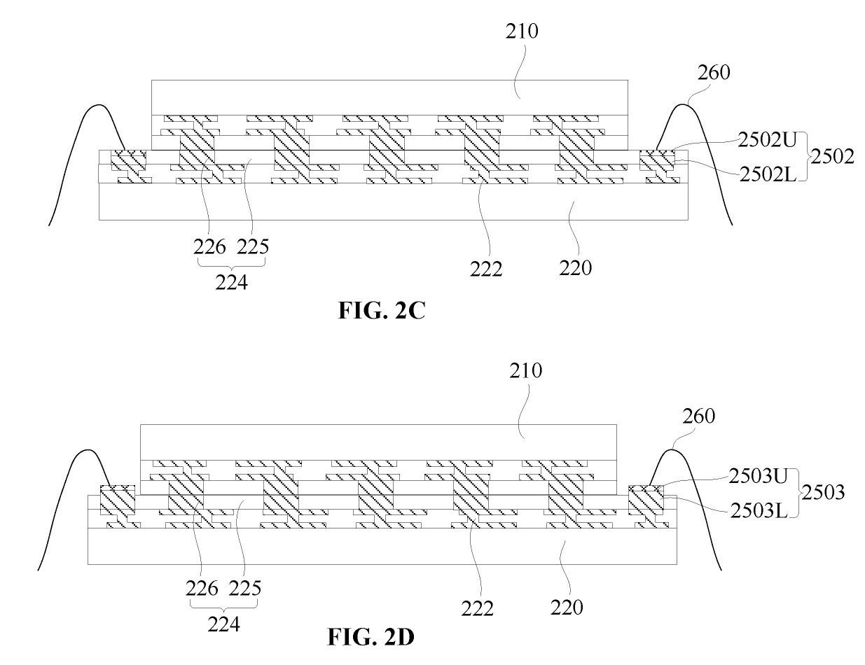

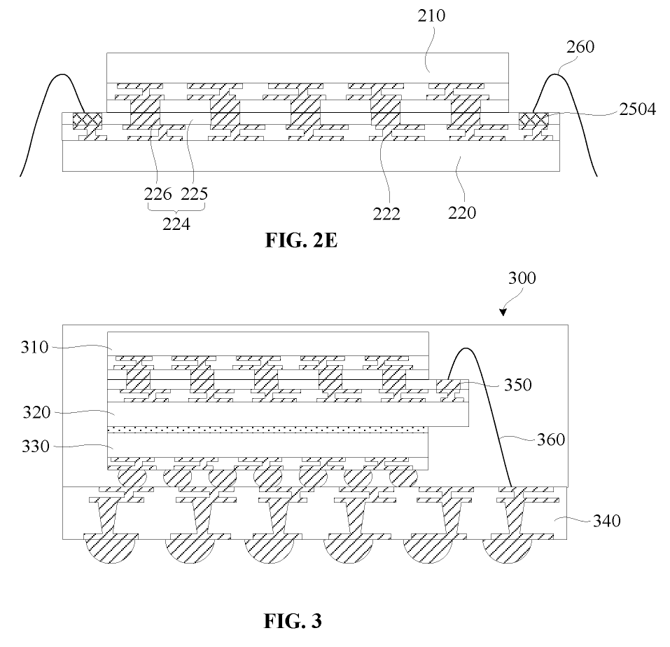

FIG. 2A illustrates a cross-sectional view of a semiconductor package 200 according to an embodiment of the present application. The semiconductor package 200 includes a first semiconductor die 210 and a second semiconductor die 220, which are bonded together using hybrid bonding.

Referring to FIG. 2B, an enlarged view of a portion 201 of the semiconductor package 200 shown in FIG. 2A is illustrated according to an embodiment of the present application. As shown in FIG. 2B, the first semiconductor die 210 has a first active surface 210a and a first non-active surface 210b opposite to the first active surface 210a, and the second semiconductor die 220 has a second active surface 220a and a second non-active surface 220b opposite to the second active surface 220a.

In some embodiments, the first semiconductor die 210 and/or the second semiconductor die 220 may include one or more digital chips, analog chips or mixed signal chips, such as application-specific integrated circuit chips, sensor chips, wireless and radio frequency chips, memory chips, logic chips or voltage regulator chips. The first semiconductor die 210 and the second semiconductor die 220 may be manufactured using a surface fabrication process or other similar processes. That is, various types of analog or digital circuits, which may be implemented as active devices and/or passive devices, may be formed close to the first active surface 210a and the second active surface 220a. In contrast, the first non-active surface 210b and the second non-active surface 220b may not have any electronic elements or any conductive patterns exposed therefrom, but the scope of this application is not limited thereto.

In some embodiments, a first redistribution layer (RDL) 212 may be formed on the first active surface 210a of the first semiconductor die 210, and a second RDL 222 may be formed on the second active surface 210a of the second semiconductor die 220. The first RDL 212 and the second RDL 222 may include one or more dielectric layers and one or more conductive layers between and through dielectric layers. The conductive layers may be electrically coupled to electronic elements formed in the first semiconductor die 210 and the second semiconductor die 220, and may also define pads, traces and plugs through which electrical signals or voltages can be distributed horizontally and vertically across the redistribution structures.

In addition, a first interconnection layer 214 may be formed on the first active surface 210a of the first semiconductor die 210. The first interconnection layer 214 may include a first dielectric layer 215 and a first plurality of conductive structures 216 extending through the first dielectric layer 215. Similarly, a second interconnection layer 224 is formed on the second active surface 220a of the second semiconductor die 220. The second interconnection layer 224 may include a second dielectric layer 225 and a second plurality of conductive structures 226 extending through the second dielectric layer 225. The first plurality of conductive structures 216 and the second plurality of conductive structures 226 may be electrically coupled to the conductive layer of the first RDL 212 and the conductive layer of the second RDL 222, respectively. In an example, the first dielectric layer 215 and the second dielectric layer 225 may include silicon oxide, while the first plurality of conductive structures 216 and the second plurality of conductive structures 226 may include copper. However, the scope of this application is not limited to these materials. The first interconnection layer 214 is attached to the second interconnection layer 224 using hybrid bonding such that the first dielectric layer 215 and the first plurality of conductive structures 216 of the first interconnection layer 214 are aligned vertically and bonded with the second dielectric layer 225 and the second plurality of conductive structures 226 of the second interconnection layer 224, respectively. The hybrid bonding can combine dielectric-to-dielectric bonding between the first dielectric layer 215 and the second dielectric layer 225 and metal-to-metal bonding between the first plurality of conductive structures 216 and the second plurality of conductive structures 226, and enables scalable and much higher interconnect density between the first semiconductor die 210 and the second semiconductor die 220. Compared to wire-bonding, hybrid bonding can significantly enhance signal transmission speed and reduce package thickness.

Further, referring to FIG. 2B, a plurality of wire-bonding pads 2501 are formed on a peripheral region of the second active surface 220a of the second semiconductor die 220. The wire-bonding pads 2501 may extend through the second dielectric layer 225 of the second interconnection layer 224 to electrically couple with the conductive layer of the second RDL 222. The wire-bonding pads 2501 may have a same height as the second plurality of conductive structures 226. That is, the upper surfaces of the wire-bonding pads 2501 are coplanar with an upper surface of the second dielectric layer 225. In an example, the wire-bonding pads 2501 and the second plurality of conductive structures 226 are formed using the same process, and include the same material, such as copper. After the first active surface 210a of the first semiconductor die 210 is attached to the second active surface 220a of the second semiconductor die 220 using hybrid bonding, the wire-bonding pads 2501 are exposed from the first semiconductor die 210. That is, the wire-bonding pads 2501 are not covered by the first semiconductor die 210.

Referring to FIG. 2C, an enlarged view of the portion 201 of the semiconductor package 200 shown in FIG. 2A is illustrated according to another embodiment of the present application. As shown in FIG. 2C, a plurality of wire-bonding pads 2502 are formed on a peripheral region of the second active surface of the second semiconductor die 220, and are exposed from the first semiconductor die 210. The wire-bonding pads 2502 may extend through the second dielectric layer 225 of the second interconnection layer 224 to electrically couple with the conductive layer of the second RDL 222. Different from the wire-bonding pads 2501 of FIG. 2B, each of the wire-bonding pads 2502 of FIG. 2C may include a lower portion 2502L and an upper portion 2502U. The wire-bonding pads 2502 may have a same height as the second plurality of conductive structures 226. That is, the upper surfaces of the upper portions 2502U of the wire-bonding pads 2502 are coplanar with the upper surface of the second dielectric layer 225. In an example, the wire-bonding pads 2502 and the second plurality of conductive structures 226 are formed using different processes. For example, the lower portion 2502L of the wire-bonding pads 2502 may include the same material as the conductive structures 226, such as copper, but the upper portions 2502U of the wire-bonding pads 2502 may include a material different from the conductive structures 226, such as gold. Gold can enable strong bonding with bonding wires (e.g., gold wires), thereby enhancing the reliability of the subsequent wire bonding process. Gold-to-gold bonding further allows for efficient diffusion, resulting in strong adhesion. In contrast, copper may oxidize easily when exposed to air, which degrades bonding quality.

Referring to FIG. 2D, an enlarged view of the portion 201 of the semiconductor package 200 shown in FIG. 2A is illustrated according to another embodiment of the present application. As shown in FIG. 2D, a plurality of wire-bonding pads 2503 are formed on a peripheral region of the second active surface of the second semiconductor die 220, and are exposed from the first semiconductor die 210. The wire-bonding pads 2503 may extend through the second dielectric layer 225 of the second interconnection layer 224 to electrically couple with the conductive layer of the second RDL 222. Unlike the wire-bonding pads 2501 of FIG. 2B, each of the wire-bonding pads 2503 of FIG. 2D may include a lower portion 2503L and an upper portion 2503U. Additionally, unlike the wire-bonding pads 2502 of FIG. 2C, the wire-bonding pads 2503 of FIG. 2D may be higher than the second plurality of conductive structures 226. That is, the upper surfaces of the upper portions 2503U of the wire-bonding pads 2503 are higher than the upper surface of the second dielectric layer 225. In an example, the lower portion 2503L of the wire-bonding pads 2503 may include the same material as the conductive structures 226, such as copper, but the upper portions 2503U of the wire-bonding pads 2503 may include a material different from the conductive structures 226, such as gold.

Referring to FIG. 2E, an enlarged view of the portion 201 of the semiconductor package 200 shown in FIG. 2A is illustrated according to still another embodiment of the present application. As shown in FIG. 2E, a plurality of wire-bonding pads 2504 are formed on a peripheral region of the second active surface of the second semiconductor die 220, and are exposed from the first semiconductor die 210. The wire-bonding pads 2504 may extend through the second dielectric layer 225 of the second interconnection layer 224 to electrically couple with the conductive layer of the second RDL 222. The wire-bonding pads 2504 may have a same height as the second plurality of conductive structures 226. The wire-bonding pads 2504 are similar to the wire-bonding pads 2501 as shown in FIG. 2B, except that the wire-bonding pads 2504 are made of a material different from that of the conductive structures 226. For example, the wire-bonding pads 2504 and the conductive structures 226 are formed using different processes. The wire-bonding pads 2504 may include gold, while the conductive structures 226 include copper.

Continuing referring to FIG. 2A, the semiconductor package 200 may further include a substrate 240 and a third semiconductor die 230. The third semiconductor die 230 is mounted on an upper surface of the substrate 240.

The substrate 240 can support the semiconductor die stack mounted thereon and further electrically connect the semiconductor die stack with other electronic components. By way of example, the substrate 240 may be a printed circuit board. However, the substrate 240 is not limited thereto. In other examples, the substrate 240 may be a semiconductor substrate, a laminate interposer, a strip interposer, a leadframe, or other suitable substrates. In accordance with the scope of the present application, the substrate 240 may include any structure on or in which integrated circuit systems are fabricated. For example, the substrate 240 may include one or more insulating or passivation layers, one or more conductive vias formed through the insulating layers, and one or more conductive layers formed over or between the insulating layers. For example, redistribution structures may be formed in the substrate 240, which include a plurality of upper conductive patterns on the upper surface of the substrate 240, a plurality of lower conductive patterns on the lower surface of the substrate 240, and a plurality of conductive vias electrically connecting at least one of the upper conductive patterns with at least one of the lower conductive patterns.

The third semiconductor die 230 may include one or more digital chips, analog chips or mixed signal chips, such as application-specific integrated circuit chips, sensor chips, wireless and radio frequency chips, memory chips, logic chips or voltage regulator chips. In a specific example, the first semiconductor die 210 and the second semiconductor die 220 are memory chips, and the third semiconductor die 230 is a logic chip. However, the present application is not limited to the above example. In some embodiments, the third semiconductor die 230 is positioned over the substrate 240 with its conductive bumps oriented toward the substrate 230, and is flip-bonded on the substrate 240. Then, the semiconductor die stack including the first semiconductor die 210 and the second semiconductor die 220 is stacked on the third semiconductor die 230. For example, an adhesive layer 235 may be formed on the upper surface of the third semiconductor die 230, and then the second non-active surface of the second semiconductor die 220 is attached to the third semiconductor die 230 via the adhesive layer 235. Further, bonding wires 260 may be used to electrically connect the wire-bonding pads (e.g., the wire-bonding pads 2501 shown in FIG. 2B, the wire-bonding pads 2502 shown in FIG. 2C, the wire-bonding pads 2503 shown in FIG. 2D, or the wire-bonding pads 2504 shown in FIG. 2E) formed on the second active surface of the second semiconductor die 220 to the conductive patterns formed on the upper surface of the substrate 240. Thus, the first semiconductor die 210 and/or the second semiconductor die 220 can be electrically connected to the third semiconductor die 230 and other electronic elements via the bonding wires 260 and the substrate 240. In some embodiments, the bonding wires 260 may include gold, copper, or aluminum.

Referring to FIG. 2A, an encapsulant 270 is formed on the substrate 240 to encapsulate the first semiconductor die 210, the second semiconductor die 220, the third semiconductor die 230 and the bonding wires 260. The encapsulant 270 can provide mechanical protection for the first semiconductor die 210, the second semiconductor die 220, the third semiconductor die 230 and the bonding wires 260. The encapsulant 270 may include, for example, an epoxy molding compound (EMC), a polymide compound, or any other suitable dielectric materials. In addition, a plurality of conductive bumps 245 are formed on the lower surface of the substrate 240. In the example shown in FIG. 2A, the conductive bumps 245 are illustrated as solder bumps, but the present application is not limited thereto. In some other embodiments, the conductive bumps 245 may include conductive pillars, copper balls, etc. In a case where the semiconductor package 200 is mounted on an external device or substrate such as a printed circuit board, the conductive bumps 245 may be used for electrically connecting the semiconductor package 200 to the external device or substrate.

While the semiconductor package of the present application is described with reference to FIGS. 2A-2E, it will be understood by those skilled in the art that modifications and adaptations to the semiconductor package may be made without departing from the scope of the present invention. For example, FIG. 3 illustrates a cross-sectional view of a semiconductor package 300 according to another embodiment of the present application. The semiconductor package 300 may include a first semiconductor die 310, a second semiconductor die 320 and a third semiconductor die 330 stacked vertically on a substrate 340. At least one wire-bonding pad 350 is formed on the second active surface of the second semiconductor die 320. A first active surface of the first semiconductor die 310 is attached to the second active surface of the second semiconductor die 320 using hybrid bonding such that the at least one wire-bonding pad 350 is exposed from the first semiconductor die 310. Bonding wires 360 are used to electrically connect the at least one wire-bonding pad 350 to the substrate 340. The semiconductor package 300 is similar to the semiconductor package 200 as shown in FIG. 2A, except that the wire-bonding pad 350 is formed near an edge of the second active surface of the second semiconductor die 320. As the bonding wires 360 are disposed on one side of the semiconductor package 300, the one-directional stacking architecture as shown in FIG. 3 can further reduce the package size.

According to another aspect of the present application, a method for forming a semiconductor package is provided.

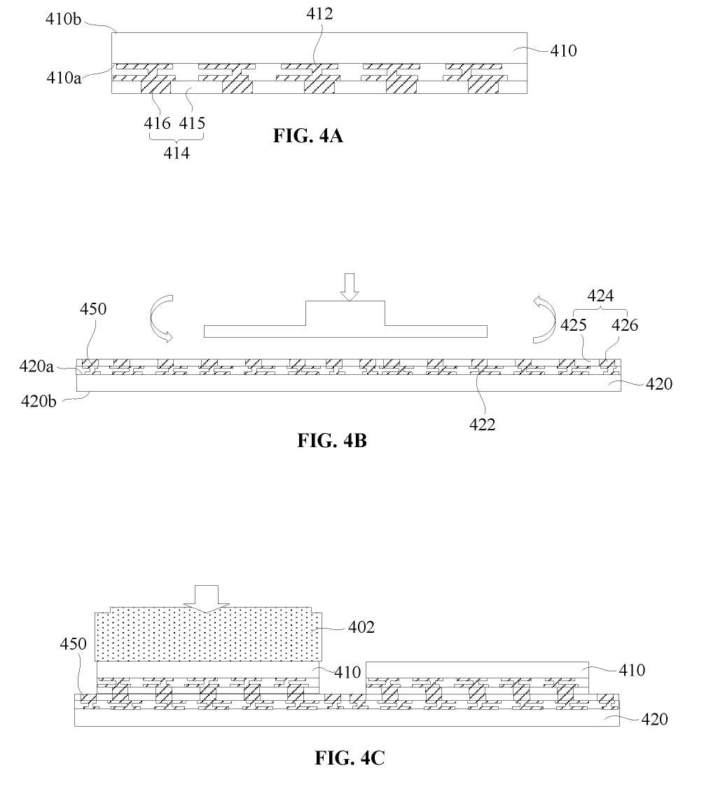

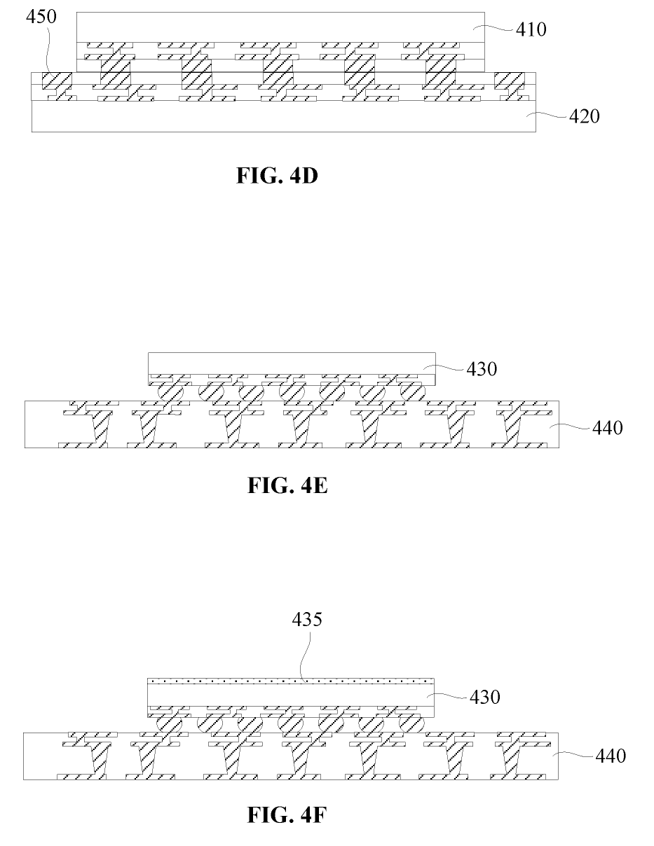

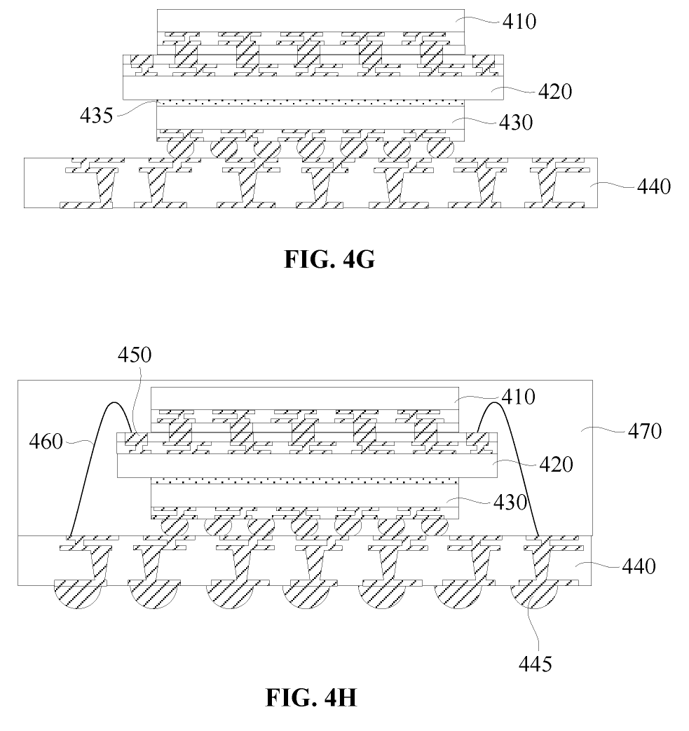

Referring to FIGS. 4A -4H, various steps of a method for forming a semiconductor package are illustrated according to an embodiment of the present application. For example, the method may be used to form the semiconductor package 200 illustrated in FIG. 2A. In the following, the method will be described with references to FIGS. 4A-4H in more details.

Referring to FIG. 4A, a first semiconductor die 410 is provided. The first semiconductor die 410 has a first active surface 410a and a first non-active surface 410b opposite to the first active surface 410a.

In some embodiments, the first semiconductor die 410 may be manufactured using a surface fabrication process or other similar processes. That is, various types of analog or digital circuits, which may be implemented as active devices and/or passive devices, may be formed close to the first active surface 410a. In contrast, the first non-active surface 410b may not have any electronic elements or any conductive patterns exposed therefrom, but the scope of this application is not limited thereto. A first redistribution layer (RDL) 412 may be formed on the first active surface 410a of the first semiconductor die 410. The first RDL 412 may include one or more dielectric layers and one or more conductive layers between and through dielectric layers. The conductive layers may be electrically coupled to electronic elements formed in the first semiconductor die 410, and may also define pads, traces and plugs through which electrical signals or voltages can be distributed horizontally and vertically across the redistribution structures. In addition, a first interconnection layer 414 may be formed on the first RDL 412. The first interconnection layer 414 may include a first dielectric layer 415 and a first plurality of conductive structures 416 extending through the first dielectric layer 415. In an example, the first dielectric layer 415 may include silicon oxide, while the first plurality of conductive structures 416 may include copper.

Referring to FIG. 4B, a second semiconductor die 420 is provided. The second semiconductor die 420 has a second active surface 420a and a second non-active surface 420b opposite to the second active surface 420a, and at least one wire-bonding pad 450 is formed on the second active surface 420a of the second semiconductor die 420.

In some embodiments, a second redistribution layer (RDL) 422 may be formed on the second active surface 420a of the second semiconductor die 420, and a second interconnection layer 424 including a second dielectric layer 425 and a second plurality of conductive structures 426 may be formed on the second RDL 422. The second semiconductor die 420 may have a similar or different structure as the first semiconductor die 410 and will not be elaborated herein. In some embodiments, the at least one wire-bonding pad 450 may be formed in a same process as the conductive structures 426 of the second interconnection layer 424, and thus the at least one wire-bonding pad 450 may extend through the second dielectric layer 425 of the second interconnection layer 424.

In some embodiments, a top portion of the second interconnection layer 424 may be grinded to form a relatively flat top surface. The grinding process can remove oxide to prepare the second semiconductor die 420 for a subsequent bonding process. For example, a chemical mechanical polishing (CMP) process may be implemented to grind the second interconnection layer 424. In some cases, a surface treatment process, for example, a plasma surface activation process may be further implemented to the upper surface of the second interconnection layer 424. It could be understood that, similar surface preparation processes may be performed on the first interconnection layer 414 of the first semiconductor die 410.

Referring to FIG. 4C, the first interconnection layer 414 of the first semiconductor die 410 is attached to the second interconnection layer 424 of the second semiconductor die 420 using hybrid bonding. After the hybrid bonding, the first dielectric layer 415 and the first plurality of conductive structures 416 of the first interconnection layer 414 are aligned vertically and bonded with the second dielectric layer 425 and the second plurality of conductive structures 426 of the second interconnection layer 424, respectively.

In some embodiments, after placing the first semiconductor die 410 onto the second semiconductor die 420, the first semiconductor die 410 is pressed against the second semiconductor die 420 by a bonding head 402. During this process, adherence occurs between the grinded surfaces of the first semiconductor die 410 and the second semiconductor die 420. This results in a strong surface-to-surface attraction and closes gaps from a center region to an edge of the aligned first semiconductor die 410 and second semiconductor die 420. This process may be conducted at a room temperature to guarantee a direct and close contact between the surfaces of the first semiconductor die 410 and the second semiconductor die 420. Next, an annealing process is implemented to the first semiconductor die 410 and the second semiconductor die 420. A fusion bonding may be established between the first and second conductive structures 416, 426 to form a strong metal-to-metal interconnection. Also, the first and second dielectric layers 415, 425 may be expanded to allow for a closer contact between each other, thereby forming a sufficient bonding therebetween. In this way, a permanent hybrid bonding, which combines dielectric-to-dielectric bonding between the first and second dielectric layers 415, 425 and metal-to-metal bonding between the first and second conductive structures 416, 426, may be formed. After the hybrid bonding, the at least one wire-bonding pad 450 should be exposed from the first semiconductor die 410.

In some embodiments, to enhance manufacturing throughput, a plurality of second semiconductor dice 420 may be formed on a same wafer in a strip manner, thereby allowing some manufacturing processes to be performed on all the plurality of second semiconductor dice 420 in parallel to form a plurality of semiconductor packages. For example, a plurality of first semiconductor dice 410 may be respectively mounted on the plurality of second semiconductor dice 420 as shown in FIG. 4C using hybrid bonding. Then, referring to FIGS. 4C and 4D, a singulation process may be performed, such that each of the first semiconductor dice 410 is bonded with one of the second semiconductor dice 420. In this way, a plurality of bilayer interconnect stacks can be formed simultaneously.

Referring to FIG. 4E, a sub-package including a substrate 440 and a third semiconductor die 430 mounted thereon is provided.

By way of example, the substrate 440 may be a printed circuit board. However, the substrate 440 is not limited thereto. In other examples, the substrate 440 may be a semiconductor substrate, a laminate interposer, a strip interposer, a leadframe, or other suitable substrates. In accordance with the scope of the present application, the substrate 440 may include any structure on or in which integrated circuit systems are fabricated. For example, the substrate 440 may include one or more insulating or passivation layers, one or more conductive vias formed through the insulating layers, and one or more conductive layers formed over or between the insulating layers. In some embodiments, the third semiconductor die 430 may include one or more digital chips, analog chips or mixed signal chips, such as application-specific integrated circuit chips, sensor chips, wireless and radio frequency chips, memory chips, logic chips or voltage regulator chips. In a specific example, the first semiconductor die 410 and the second semiconductor die 420 are memory chips, and the third semiconductor die 430 is a logic chip. However, the present application is not limited to the above example. In some embodiments, the third semiconductor die 430 is positioned over the substrate 440 with its conductive bumps oriented toward the substrate 430, and is flip-bonded on the substrate 440.

Referring to FIG. 4F, an adhesive layer 435 is formed on the upper surface of the third semiconductor die 430. The adhesive layer 435 may be a double-sided tape. For example, the adhesive layer 435 may be an ultraviolet sensitive tape, which may be hardened after irradiation by ultraviolet light with a certain wavelength range. In another example, the adhesive layer 435 may include adhesive materials such as adhesive polymer, plastic, ceramics or the like. Then, as shown in FIG. 4G, the second non-active surface of the second semiconductor die 420 is attached to the third semiconductor die 430 via the adhesive layer 435.

Afterwards, referring to FIG. 4H, the at least one wire-bonding pad 450 is electrically coupled to the substrate 440 using wire bonding. For example, bonding wires 460 may be used to electrically connect the at least one wire-bonding pad 450 formed on the second active surface of the second semiconductor die 420 to conductive patterns formed on the upper surface of the substrate 440. Thus, the first semiconductor die 410 and/or the second semiconductor die 420 can be electrically connected to the third semiconductor die 430 and other electronic elements via the bonding wires 460 and the conductive patterns formed in the substrate 440. In some embodiments, the bonding wires 460 may include gold, copper, or aluminum.

Further, an encapsulant 470 may be formed on the substrate 440 to encapsulate the first semiconductor die 410, the second semiconductor die 420, the third semiconductor die 430 and the bonding wires 460. The encapsulant 470 can provide mechanical protection for the first semiconductor die 410, the second semiconductor die 420, the third semiconductor die 430 and the bonding wires 460. The encapsulant 470 may include, for example, an epoxy molding compound (EMC), a polymide compound, or any other suitable dielectric materials. In addition, a plurality of conductive bumps 445 are formed on the lower surface of the substrate 440. In a case where the semiconductor package is mounted on an external device or substrate such as a printed circuit board, the conductive bumps 445 may be used for electrically connecting the semiconductor package to the external device or substrate.

In the above embodiments described with reference to FIGS. 4A-4H, the fabrication process of the semiconductor package is described using a semiconductor die stack similar as that shown in FIG. 2B. However, the present application is not limited thereto. In some other embodiments, a semiconductor die stack similar as those shown in FIGS. 2C-2E can also be used to form the semiconductor package. In the following, the method for forming the semiconductor die stacks as shown in FIGS. 2C-2E will be described in more details.

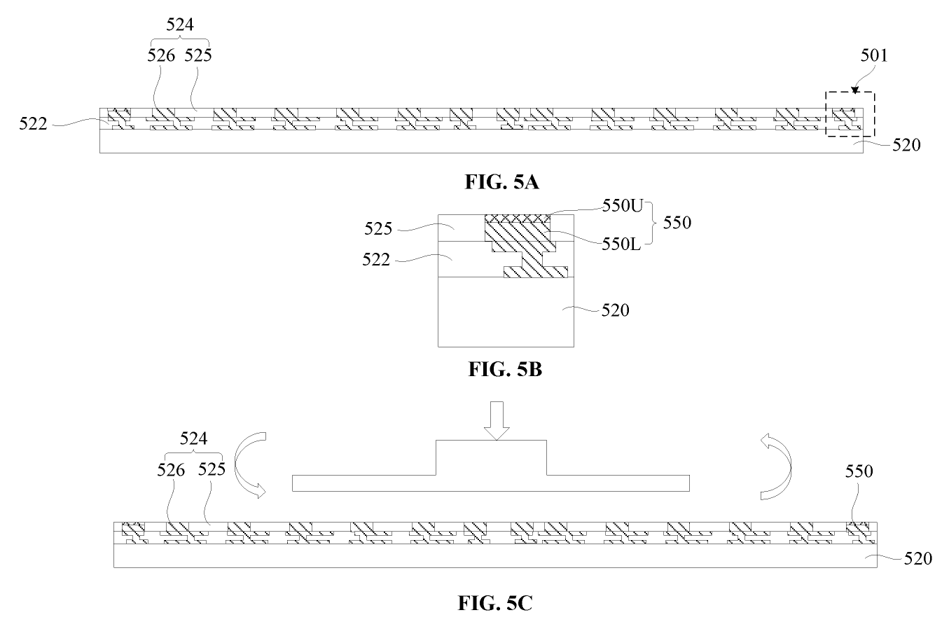

Referring to FIGS. 5A-5C, a method for forming the semiconductor die stack as shown in FIG. 2C is provided.

As shown in FIG. 5A, a second semiconductor die 520 is provided. The second semiconductor die 520 has an active surface and a non-active surface opposite to the active surface. A second RDL 522 may be formed on the active surface of the second semiconductor die 520, and a second interconnection layer 524 including a second dielectric layer 525 and a second plurality of conductive structures 526 may be formed on the second RDL 522. Referring to FIG. 5B, an enlarged view of the portion 501 of the second semiconductor die 520 shown in FIG. 5A is illustrated. As shown in FIG. 5B, a wire-bonding pad 550 is formed on the active surface of the second semiconductor die 520. The wire-bonding pad 550 may extend through the second dielectric layer 525 of the second interconnection layer 524 to electrically couple with the conductive layer of the second RDL 522. The wire-bonding pad 550 of FIG. 5B may include a lower portion 550L and an upper portion 550U. The wire-bonding pad 550 may have a same height as the second plurality of conductive structures 526. That is, the upper surface of the upper portion 550U is coplanar with the upper surface of the second dielectric layer 525. Different from the wire-bonding pad 450 shown in FIG. 4B, the wire-bonding pad 550 and the second plurality of conductive structures 526 are formed using different processes. For example, the lower portion 550L of the wire-bonding pad 550 may include the same material as the conductive structures 526, such as copper, but is lower than the second plurality of conductive structures 526. Then, gold electroless immersion may be performed on the lower portion 550L to form the upper portion 550U to match the height. As a result, the overall height of the wire-bonding pad 550 is the same as that of the second plurality of conductive structures 526. Then, as shown in FIG. 5C, a grinding process may be performed on the upper surface of the second semiconductor die 520 for a subsequent bonding process.

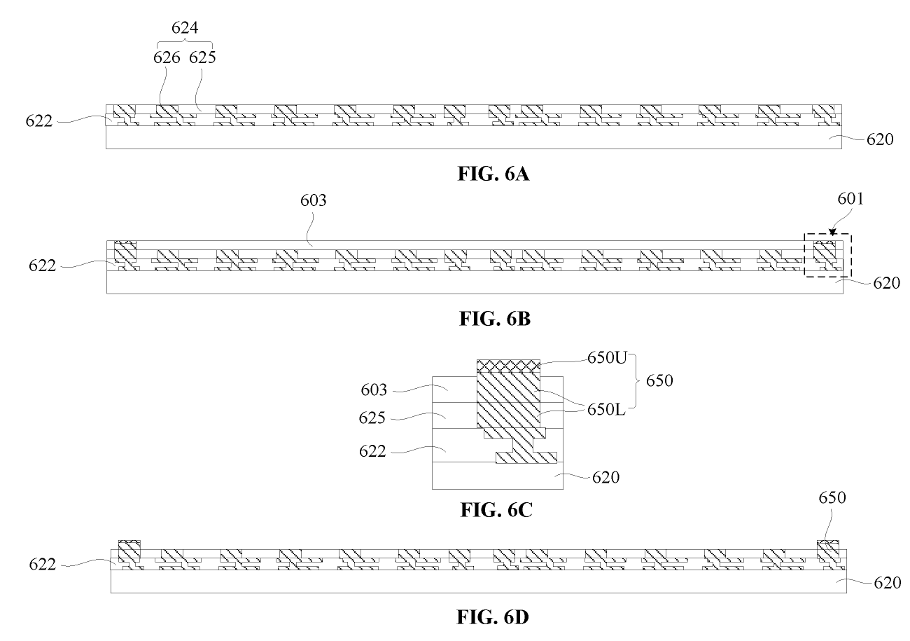

Referring to FIGS. 6A-6D, a method for forming the semiconductor die stack as shown in FIG. 2D is provided.

As shown in FIG. 6A, a second semiconductor die 620 is provided. The second semiconductor die 620 has an active surface and a non-active surface opposite to the active surface. A second RDL 622 may be formed on the active surface of the second semiconductor die 620, and a second interconnection layer 624 including a second dielectric layer 625 and a second plurality of conductive structures 626 may be formed on the second RDL 622. Referring to FIGS. 6B and 6C, FIG. 6C is an enlarged view of the portion 601 of the second semiconductor die 620 shown in FIG. 6B. A wire-bonding pad 650 is formed on the active surface of the second semiconductor die 620. The wire-bonding pad 650 may extend through the second dielectric layer 625 of the second interconnection layer 624 to electrically couple with the conductive layer of the second RDL 622. The wire-bonding pad 650 of FIG. 6C may include a lower portion 650L and an upper portion 650U. The wire-bonding pad 650 may be higher than the second plurality of conductive structures 626. That is, the upper surface of the upper portion 650U of the wire-bonding pad 650 is higher than the upper surface of the second dielectric layer 625. In an example, a photoresist layer 603 may be formed on the upper surface of the second semiconductor die 620, and the photoresist layer 603 is patterned to expose the lower portion 650L of the wire-bonding pad 650. Then, an additional copper layer is deposited on the lower portion 650L to increase its height, and then a gold layer is deposited on the additional copper layer to form the upper portion 650U. By way of example, the additional copper layer and the gold layer may be deposited by electro-plating. Then, as shown in FIG. 6D, the photoresist layer 603 may be chemically removed. The wire-bonding pad 650 can be protected using a hard mask or resist before performing a chemical mechanical polishing (CMP) process for selective grinding the conductive structures 626. For example, silicon oxide may be deposited to a certain thickness such that only the ends of the wire-bonding pad 650 are exposed.

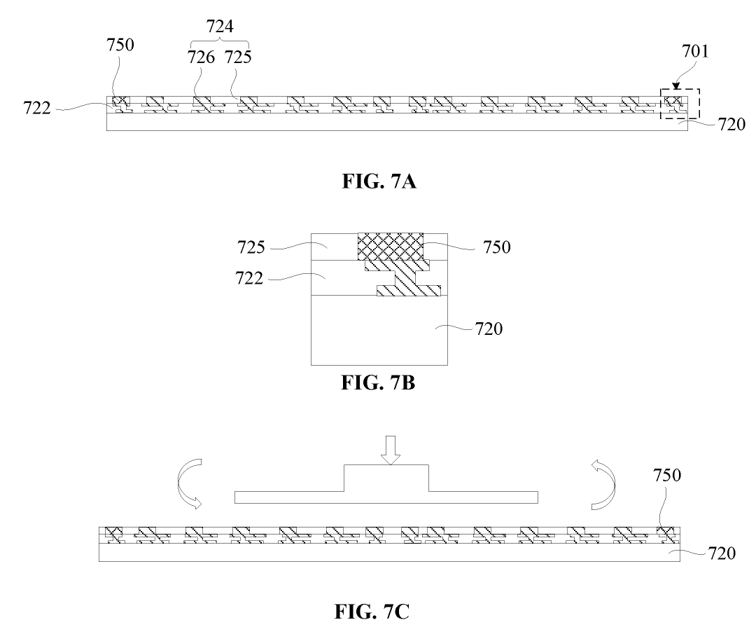

Referring to FIGS. 7A-7C, a method for forming the semiconductor die stack as shown in FIG. 2E is provided.

As shown in FIG. 7A, a second semiconductor die 720 is provided. The second semiconductor die 720 has an active surface and a non-active surface opposite to the active surface. A second RDL 722 may be formed on the active surface of the second semiconductor die 720, and a second interconnection layer 724 including a second dielectric layer 725 and a second plurality of conductive structures 726 may be formed on the second RDL 722. Referring to FIG. 7B, an enlarged view of the portion 701 of the second semiconductor die 720 shown in FIG. 7A is illustrated. As shown in FIG. 7B, a wire-bonding pad 750 is formed on the active surface of the second semiconductor die 720. The wire-bonding pad 750 may extend through the second dielectric layer 725 of the second interconnection layer 724 to electrically couple with the conductive layer of the second RDL 722. Different from the wire-bonding pad 450 shown in FIG. 4B, the wire-bonding pad 750 and the second plurality of conductive structures 726 are formed using different processes. For example, the wire-bonding pad 750 is formed by depositing gold in some through holes in the second dielectric layer 725, while the second plurality of conductive structures 726 are formed by depositing copper in other through holes in the second dielectric layer 725. Then, as shown in FIG. 7C, a grinding process may be performed on the upper surface of the second semiconductor die 720 for a subsequent bonding process.

While the exemplary semiconductor package and the method for forming the semiconductor package of the present application are described in conjunction with corresponding figures, it will be understood by those skilled in the art that modifications and adaptations to the semiconductor package and the method may be made without departing from the scope of the present invention. The discussion herein included numerous illustrative figures that showed various portions of a semiconductor package and a method for making the same. For illustrative clarity, such figures did not show all aspects of each exemplary semiconductor package. Any of the example packages and/or methods provided herein may share any or all characteristics with any or all other packages and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a semiconductor package, comprising:
providing a first semiconductor die having a first active surface and a first non-active surface opposite to the first active surface;
providing a second semiconductor die having a second active surface and a second non-active surface opposite to the second active surface, wherein at least one wire-bonding pad is formed on the second active surface of the second semiconductor die;
attaching the first active surface of the first semiconductor die to the second active surface of the second semiconductor die using hybrid bonding, wherein the at least one wire-bonding pad is exposed from the first semiconductor die;
providing a sub-package comprising a substrate and a third semiconductor die mounted on the substrate;
attaching the second non-active surface of the second semiconductor die to the third semiconductor die; and
electrically coupling the at least one wire-bonding pad to the substrate using wire bonding.

2. The method of claim 1, wherein attaching the second non-active surface of the second semiconductor die to the third semiconductor die comprises:
forming an adhesive layer on the third semiconductor die; and
attaching the second non-active surface of the second semiconductor die to the third semiconductor die via the adhesive layer.

3. The method of claim 1, further comprising:
forming an encapsulant on the substrate to encapsulate the first semiconductor die, the second semiconductor die, and the third semiconductor die.

4. The method of claim 1, wherein attaching the first active surface of the first semiconductor die to the second active surface of the second semiconductor die using hybrid bonding comprising:
forming a first interconnection layer on the first active surface of the first semiconductor die, wherein the first interconnection layer comprises a first dielectric layer and a first plurality of conductive structures extending through the first dielectric layer;
forming a second interconnection layer on the second active surface of the second semiconductor die, wherein the second interconnection layer comprises a second dielectric layer and a second plurality of conductive structures extending through the second dielectric layer; and
attaching the first interconnection layer to the second interconnection layer using hybrid bonding such that the first dielectric layer and the first plurality of conductive structures of the first interconnection layer are aligned vertically and bonded with the second dielectric layer and the second plurality of conductive structures of the second interconnection layer, respectively.

5. The method of claim 4, wherein the at least one wire-bonding pad extends through the second dielectric layer of the second interconnection layer.

6. The method of claim 5, wherein the at least one wire-bonding pad comprises copper or gold.

7. The method of claim 5, wherein the at least one wire-bonding pad comprises a lower portion comprising copper and an upper portion comprising gold.

8. The method of claim 5, wherein an upper surface of the at least one wire-bonding pad is coplanar with an upper surface of the second dielectric layer, or higher than an upper surface of the second dielectric layer.

9. The method of claim 1, wherein the at least one wire-bonding pad is formed on a peripheral region of the second active surface of the second semiconductor die.

10. The method of claim 1, wherein the at least one wire-bonding pad is formed near an edge of the second active surface of the second semiconductor die.

11. A semiconductor package, comprising:
a first semiconductor die having a first active surface and a first non-active surface opposite to the first active surface;
a second semiconductor die having a second active surface and a second non-active surface opposite to the second active surface, wherein at least one wire-bonding pad is formed on the second active surface of the second semiconductor die, and the first active surface of the first semiconductor die is attached to the second active surface of the second semiconductor die using hybrid bonding such that the at least one wire-bonding pad is exposed from the first semiconductor die; and
a sub-package comprising a substrate and a third semiconductor die mounted on the substrate, wherein the second non-active surface of the second semiconductor die is attached to the third semiconductor die, and the at least one wire-bonding pad is electrically coupled to the substrate using wire bonding.

12. The semiconductor package of claim 11, further comprising:
an adhesive layer formed on the third semiconductor die, wherein the second non-active surface of the second semiconductor die is attached to the third semiconductor die via the adhesive layer.

13. The semiconductor package of claim 11, further comprising:
an encapsulant formed on the substrate to encapsulate the first semiconductor die, the second semiconductor die, and the third semiconductor die.

14. The semiconductor package of claim 11, further comprising:
a first interconnection layer formed on the first active surface of the first semiconductor die, wherein the first interconnection layer comprises a first dielectric layer and a first plurality of conductive structures extending through the first dielectric layer; and
a second interconnection layer formed on the second active surface of the second semiconductor die, wherein the second interconnection layer comprises a second dielectric layer and a second plurality of conductive structures extending through the second dielectric layer,
wherein the first interconnection layer is attached to the second interconnection layer using hybrid bonding such that the first dielectric layer and the first plurality of conductive structures of the first interconnection layer are aligned vertically and bonded with the second dielectric layer and the second plurality of conductive structures of the second interconnection layer, respectively.

15. The semiconductor package of claim 14, wherein the at least one wire-bonding pad extends through the second dielectric layer of the second interconnection layer.

16. The semiconductor package of claim 15, wherein the at least one wire-bonding pad comprises copper or gold.

17. The semiconductor package of claim 15, wherein the at least one wire-bonding pad comprises a lower portion comprising copper and an upper portion comprising gold.

18. The semiconductor package of claim 15, wherein an upper surface of the at least one wire-bonding pad is coplanar with an upper surface of the second dielectric layer, or higher than the upper surface of the second dielectric layer.

19. The semiconductor package of claim 11, wherein the at least one wire-bonding pad is formed on a peripheral region of the second active surface of the second semiconductor die.

20. The semiconductor package of claim 11, wherein the at least one wire-bonding pad is formed near an edge of the second active surface of the second semiconductor die.
